(19) United States
(12) Patent Application Publication
(10) Pub. No.: US 2026/0293674 A1
(43) Pub. Date: Sep. 24, 2026

(54) INTEGRATED CIRCUITS WITH FUSION-BONDED DIAMOND SUBSTRATES FOR THERMAL MANAGEMENT

(71) Applicant: Intel Corporation, Santa Clara, CA (US)

(72) Inventors: Seyed Hadi Zandavi, Phoenix, AZ (US); Xavier F. Brun, Chandler, AZ (US); Yi Yang, Gilbert, AZ (US); Je-Young Chang, Tempe, AZ (US); Yuvraj Singh, Chandler, AZ (US); Pilin Liu, Chandler, AZ (US); Yoshihiro Tomita, Tsukuba-Shi (JP)

(73) Assignee: Intel Corporation, Santa Clara, CA (US)

(21) Appl. No.: 19/087,864

(22) Filed: Mar. 24, 2025

(51) Int. Cl. H01L 23/373; H01L 23/00; H01L 25/18; H10B 80/00; H10D 80/30

(52) U.S. Cl. CPC H10W 40/254; H10W 90/00; H10B 80/00; H10D 80/30; H10W 72/01351; H10W 72/01353; H10W 72/01365; H10W 72/0198; H10W 72/073; H10W 72/07311; H10W 72/07331; H10W 72/353; H10W 72/355; H10W 90/734

(57) ABSTRACT

Devices and systems with diamond substrates bonded to integrated circuits, and methods of forming the same, are disclosed herein. In one example, a microelectronic assembly includes a semiconductor substrate, a diamond substrate, a first dielectric layer on the semiconductor substrate, and a second dielectric layer on the diamond substrate, where the second dielectric layer is bonded to the first dielectric layer.

### BACKGROUND

Three-dimensional heterogeneous integration (3DHI) is an advanced packaging technology where multiple semiconductor dies are vertically integrated, or stacked, in a single integrated circuit package to increase transistor density. This approach allows multiple dies to be stacked on top of each other and connected through dense high-speed interconnects with shorter interconnect lengths, which enables higher performance and more functionality to be achieved in smaller form factors. Effective thermal management is crucial for 3D stacked die packages, however, particularly in view of the trend towards higher-density packages with more stacked dies, which leads to higher heat output during operation. In particular, insufficient cooling of high-density 3D stacked die packages can reduce their performance and reliability over time.

### BRIEF DESCRIPTION OF THE DRAWINGS

FIG. 1 illustrates a microelectronic assembly with a fusion-bonded diamond substrate.

FIGS. 2A-C illustrate a process flow for die-to-die fusion bonding of diamond to integrated circuitry.

FIGS. 3A-C illustrate a process flow for die-to-wafer fusion bonding of diamond to integrated circuitry.

FIGS. 4A-C illustrate a process flow for wafer-to-wafer fusion bonding of diamond to integrated circuitry.

FIG. 5 illustrates a flowchart for fusion bonding a diamond substrate to a semiconductor substrate using dielectric film.

FIG. 6 illustrates a system with fusion-bonded diamond heat spreaders in accordance with certain embodiments.

FIGS. 7A-B illustrate graphs of thermal cycling tests performed on a device with a fusion-bonded diamond substrate.

FIG. 8 illustrates a top view of a wafer and dies that may be included in a microelectronic assembly.

FIG. 9 illustrates a cross-sectional view of an integrated circuit device that may be included in a microelectronic assembly.

FIG. 10 illustrates a cross-sectional view of an integrated circuit device assembly that may include a microelectronic assembly.

FIG. 11 illustrates a block diagram of an example electrical device that may include a microelectronic assembly.

### DETAILED DESCRIPTION

Three-dimensional (3D) heterogeneous integration (3DHI) is an advanced packaging technology where multiple semiconductor dies are vertically integrated, or stacked, in a single integrated circuit (IC) package to increase transistor density. This approach allows multiple dies to be stacked on top of each other and connected through dense high-speed interconnects with shorter interconnect lengths (e.g., using interconnect technologies such as through-silicon vias (TSVs), hybrid bonding, and/or micro-bumps), which enables higher performance and more functionality to be achieved in smaller form factors across various markets.

Effective thermal management (e.g., heat dissipation and cooling) is crucial for 3D stacked die packages, however, particularly in view of the trend towards higher-density packages with more stacked dies, which leads to higher heat output during operation. In particular, insufficient cooling can impact the long-term reliability of active devices within a dense 3D stacked die package, which may lead to lower performance and even failure over time. Effectively cooling 3D stacked die packages remains challenging, however, and more efficient heat removal solutions are needed for high-density packages with high heat output.

In some cases, materials with high thermal conductivity—such as diamond, silicon carbide (SiC), or graphite—may be used to help with thermal management. In particular, diamond has extremely high thermal conductivity, which means it can be used as a very effective heat spreader. For example, diamond can be bonded to a semiconductor chip to spread heat towards a heat sink with very high efficiency to help dissipate hot spots.

To achieve an effective cooling solution, it is crucial to position diamond close to the active circuitry where heat is generated, which requires diamond to be bonded to dies, chiplets, or wafers. However, current approaches for bonding diamond to active semiconductor substrates have various drawbacks. For example, some methods require a very smooth diamond surface to achieve a strong bond, which requires complex processing and leads to higher costs. Some methods require wet activation, which involves harsh chemicals that may be incompatible with standard processes (e.g., hybrid bonding) used in die stacking technologies. Some methods require extreme conditions to achieve a strong bond, such as high temperature and high pressure, which requires the process to be carefully controlled to avoid damaging delicate components, thus increasing cost and complexity and presenting various challenges relating to equipment requirements, applicability to wafer-level bonding, impact on the materials involved, etc. Some methods produce a bond with low thermal conductivity, which impedes the transfer of heat from the chip to the diamond and decreases heat spreading efficiency. Finally, no high-volume manufacturing (HVM) solutions are suitable for bonding diamond at the die or package level.

Accordingly, this disclosure presents embodiments of integrated circuits with fusion-bonded diamond substrates for thermal management, along with methods of forming the same. In particular, to effectively address the challenges associated with bonding diamond substrates to active semiconductor substrates (e.g., silicon (Si)) dies and chiplets), dielectric layers are formed on the bonding surfaces of the diamond and semiconductor substrates, and the respective dielectric layers are fusion bonded to each other using plasma-enhanced bonding techniques.

In some embodiments, for example, a thin dielectric layer is formed on the bonding surface of the diamond substrate, and a corresponding thin dielectric layer is formed on the bonding surface of the active semiconductor substrate. The dielectric layers may be polished (e.g., using chemical mechanical polishing (CMP)) to achieve smooth bonding surfaces. Next, plasma-enhanced bonding is employed to fusion bond the dielectric layers together, forming a direct dielectric-to-dielectric bond at the interface between the dielectric layers, such that the diamond substrate is attached to the semiconductor substrate via the bonded dielectric layers. Finally, the bonded assembly is annealed at an elevated temperature to enhance the strength of the bond.

In this manner, diamond substrates with high thermal conductivity can be bonded to active (e.g., silicon) dies/chiplets to suppress hot spots in 3D heterogeneously-integrated (3DHI) packages. The dielectric layers facilitate a compatible and strong interface for bonding, leveraging their insulating and surface bonding properties. Moreover, bonding can be performed at the die level and/or the wafer level, including die-to-die bonding, wafer-to-wafer bonding, and die-to-wafer bonding.

The described embodiments may provide various advantages. For example, the described bonding approach can be implemented using existing bonding process flows that are readily available for wafer-level and die-level packaging and assembly, with low implementation costs. For example, dielectric deposition, chemical mechanical polishing/planarization (CMP), and hybrid bonding are well-established technologies that have been used in the industry for front and back end-of-line (FEOL and BEOL) processing, along with wafer-level assembly processing. As a result, these technologies can be leveraged to implement the described diamond bonding process with relative ease. For example, the principles of hybrid bonding (e.g., to form a hybrid bond interconnect with dielectric-to-dielectric and metal-to-metal bonds), also referred to as direct bonding, can be applied to the described diamond bonding process to fusion bond the dielectric layers together on the respective bonding surfaces.

The described approach also eliminates the need to use diamond substrates with smooth high-quality surfaces (e.g., with a surface roughness below 0.5 nanometers (nm)), which reduces the cost of the diamond substrates. In particular, by applying a dielectric layer over a diamond substrate and polishing the surface of the dielectric layer to achieve a desired surface roughness, the diamond substrate can have a relatively rough surface (e.g., with surface roughness of 0.5 nm or higher) since the dielectric layer serves as the bonding surface.

Moreover, the bonded interface between the dielectric layers has low thermal resistance (e.g., less than 0.005 square centimeters kelvin per watt (cm² K/W) in some cases), which facilitates the transfer of heat from the semiconductor device to the diamond substrate.

Further, the described bonding process can also be applied to other types of substrates with high thermal conductivity, such as substrates made of silicon carbide or graphite.

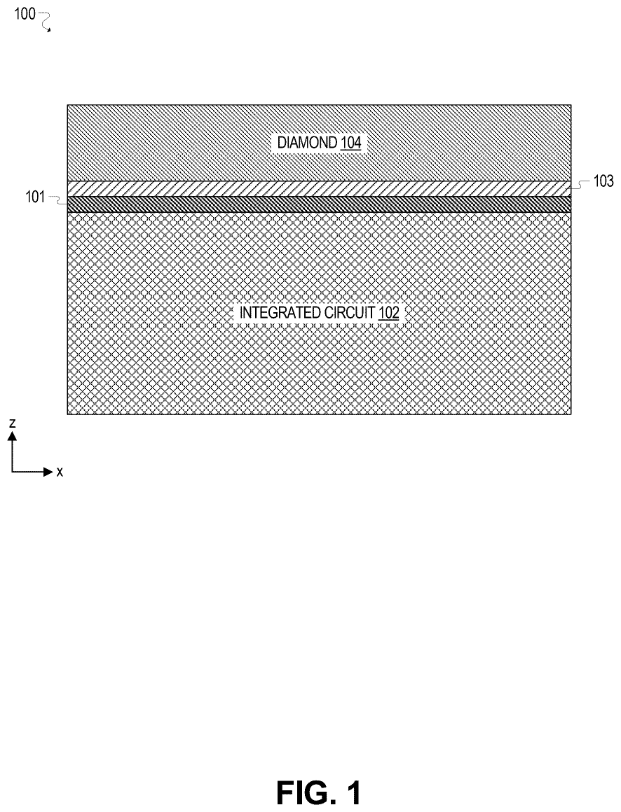

FIG. 1 illustrates a cross-section (x-z plane) view of an example microelectronic assembly 100 with a fusion-bonded diamond substrate 104. In the illustrated embodiment, microelectronic assembly 100 includes an integrated circuit (IC) 102 with a diamond substrate 104 attached on top of the IC 102 via fusion-bonded dielectric layers 101, 103. In particular, the IC 102 and the diamond substrate 104 each have a dielectric layer 101, 103 on one of their surfaces, and the diamond substrate 104 is attached on top of the IC 102 with the respective dielectric layers 101, 103 fusion bonded together. In this manner, the IC 102 and the diamond substrate 104 are attached via a direct dielectric-to-dielectric bond at the interface between the dielectric layers 101, 103.

In some embodiments, the diamond substrate 104 may be attached to the IC 102 using the process flow described throughout this disclosure. For example, the dielectric layers 101, 103 may be formed on the respective bonding surfaces of the IC 102 and the diamond substrate 104. In various embodiments, the dielectric layer 101 on the IC 102 may be formed during fabrication of the IC 102 (e.g., as part of the standard process flow for fabricating the IC 102), or alternatively, the dielectric layer 101 may be formed on the IC 102 after fabrication is complete (e.g., separate from the standard process flow for fabricating the IC 102).

The dielectric layers 101, 103 may then be polished or planarized to achieve a smooth surface (e.g., with a surface roughness of less than 0.2 nm in some cases), which helps facilitate a strong bond.

The dielectric layers 101, 103 may then be fusion bonded together using plasma-enhanced bonding techniques. For example, the surface of the respective dielectric layers 101, 103 may be activated using a plasma activation and hydration treatment. The diamond substrate 104 may then be placed on top of the IC 102 with their respective dielectric layers 101, 103 in contact, the activated dielectric layers 101, 103 may be fusion bonded directly together at room temperature. Finally, the bonded assembly 100 may be annealed at an elevated temperature to increase the strength of the bond.

To achieve an effective cooling solution, it is crucial to position the diamond substrate 104 as close as possible to the active circuitry (e.g., in IC 102) where heat is generated. In the illustrated embodiment, the requisite proximity is achieved by attaching the diamond substrate 104 on top of the IC 102 via fusion-bonded dielectric layers 101, 103. In this manner, when hot spots develop on the IC 102 during operation, heat from the hot spots is transferred from the IC 102 to the diamond substrate 104. Due to the high thermal conductivity of the diamond substrate 104, the heat spreads efficiently through the diamond substrate 104—and optionally through other thermal management components (e.g., a heat sink 618) that are thermally coupled to the diamond substrate 104—and the heat eventually dissipates, thus suppressing the hot spots.

In the illustrated embodiment, the IC 102 may include one or more IC dies. In some embodiments, for example, IC 102 may include multiple IC dies that are vertically integrated or stacked using 3DHI packaging techniques. In some embodiments, each IC die may be formed on a semiconductor substrate, such as a silicon substrate. In various embodiments, IC 102 may be referred to as an IC, an IC die, an IC die stack, an IC package, a semiconductor substrate, and variations thereof.

The diamond substrate 104 may include any suitable type of diamond material (e.g., single-crystal diamond (SCD), polycrystalline diamond (PCD), nanocrystalline diamond (NCD), ultra-nanocrystalline diamond (UNCD)) in any suitable form (e.g., bulk diamond, diamond thin film). In some embodiments, the thermal conductivity of the diamond substrate 104 may be higher than 2000 watts per meter kelvin (W/mK). The diamond substrate 104 may also be referred to as a diamond, diamond layer, diamond die, diamond chiplet, diamond wafer, and variations thereof. In some embodiments, the diamond substrate 104 may be replaced with another type of substrate with high thermal conductivity, such as a substrate made of silicon carbide (SiC) or graphite.

The dielectric layers 101, 103 may include any type or combination of dielectric materials with any applicable level of hydrogenation and any stoichiometric ratio. In some embodiments, for example, the respective dielectric layers 101, 103 may include, without limitation, silicon nitride (SiN), silicon dioxide (SiO₂), silicon carbonitride (SiCN), silicon carbide (SiC), silicon oxycarbide (SiOC), silicon oxynitride (SiON), silicon oxycarbonitride (SiOCN), aluminum oxide (Al₂O₃), and/or thermal oxides (e.g., thermally-grown silicon oxide (SiOₓ)). As an example, the dielectric layer 101 on the IC 102 may include silicon oxide (e.g., SiO₂), and the dielectric layer 103 on the diamond substrate 104 may include silicon nitride (e.g., SiN) or aluminum oxide (e.g., Al₂O₃). Thus, in some embodiments, the respective dielectric layers 101, 103 may include elements such as (i) silicon and nitrogen, (ii) silicon and oxygen, (iii) silicon, carbon, and nitrogen, (iv) silicon and carbon, (v) silicon, oxygen, and carbon, (vi) silicon, oxygen, and nitrogen, (vii) silicon, oxygen, carbon, and nitrogen, or (viii) aluminum and oxygen. As an example, the dielectric layer 101 on the IC 102 may include elements such as silicon and oxygen, and the dielectric layer 103 on the diamond substrate 104 may include elements such as (i) silicon and nitrogen or (ii) aluminum and oxygen.

Moreover, the respective dielectric layers 101, 103 may have any suitable thickness. In some embodiments, the dielectric layer 101 on the IC 102 may have a thickness in the range of about 50 nm to 1 micron (μm), and the dielectric layer 103 on the diamond substrate 104 may have a thickness in the range of about 50 nm to 100 nm.

Plasma-enhanced bonding may also be referred to as plasma-activated bonding, plasma fusion bonding, plasma bonding, and variations thereof.

Microelectronic assembly 100 may also be referred to as an integrated circuit (IC), an IC package, a semiconductor device, an electronic device, and variations thereof.

It should be appreciated that microelectronic assembly 100 is merely shown as an example and numerous variations and alternative embodiments are also within the scope of this disclosure. In various embodiments, for example, certain elements of microelectronic assembly 100 may be modified, replaced, rearranged, omitted, and/or added. As an example, dielectric layers 101, 103 may include other types or combinations of dielectric materials besides those disclosed herein. IC 102 may include any number of IC dies, which may be stacked or integrated vertically in some embodiments. IC 102 may also include any suitable type of interconnects between stacked dies, including, without limitation, hybrid bond interconnects (HBI), micro ball grid array (μBGA) interconnects, and/or ball grid array (BGA) interconnects. Further, while the described embodiments use diamond substrates 104, other embodiments may use other types of substrates with high thermal conductivity instead of diamond substrates 104, such as substrates made of silicon carbide (SiC) or graphite. Microelectronic assembly 100 may also include other elements not shown in the illustrated embodiment for the sake of simplicity.

The concepts described above for microelectronic assembly 100, including any modifications thereof, also apply to the other embodiments in this disclosure (and vice versa), including microelectronic assemblies 200a-d, 300a-d, 400a-d and system 600.

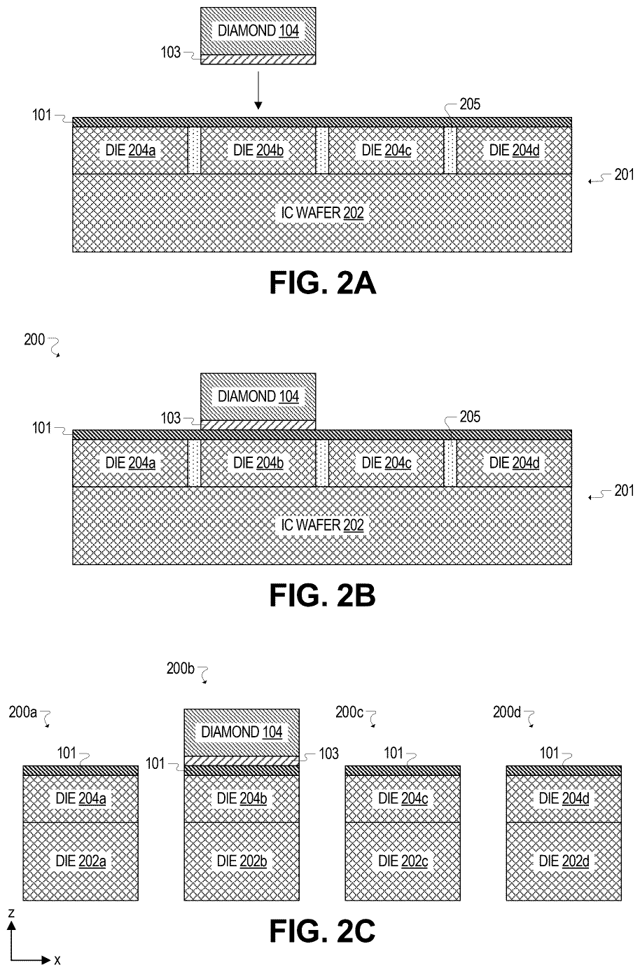

FIGS. 2A-C illustrate an example process flow for die-to-die fusion bonding of diamond to integrated circuitry (e.g., top die bonded to base IC wafer). In the illustrated example, FIGS. 2A-C show cross-section (x-z plane) views from various steps of the process flow.

In FIG. 2A, a semiconductor wafer assembly 201 and a diamond die 104 are received, their dielectric surfaces 101, 103 are cleaned and activated, and the diamond die 104 is placed on top of one of the dies 204b on the wafer assembly 201.

In particular, the diamond die 104 includes a dielectric layer 103 on the surface of one side. The wafer assembly 201 includes a base integrated circuit (IC) wafer 202, which is a processed semiconductor (e.g., silicon) wafer with multiple unsingulated IC dies (not shown). The base IC wafer 202 may also be referred to as an IC wafer, a base wafer, a processed wafer, a finished wafer, an unsingulated wafer, a wafer with dies, a semiconductor wafer, an IC substrate, and variations thereof. The wafer assembly 201 also includes multiple singulated IC dies 204a-d attached on top of the base IC wafer 202 (e.g., attached to the unsingulated IC dies in the base wafer 202), along with dielectric fill 205 in the gaps between the dies 204a-d. Finally, the wafer assembly 201 includes a dielectric layer 101 on the surface above the dies 204a-d.

The dielectric layers 101, 103 on the surface of the wafer assembly 201 and the diamond die 104, respectively, are cleaned and then activated using a plasma activation and hydration treatment. The diamond die 104 is then placed on top of the wafer assembly 201—over one of the singulated IC dies 204b attached to the base IC wafer 202—with their respective dielectric layers 103, 101 in contact with each other.

In FIG. 2B, the plasma-activated dielectric layers 101, 103 on the wafer assembly 201 and the diamond die 104 are fusion bonded to each other at room temperature, thus forming a direct dielectric-to-dielectric bond at the interface between the dielectric layers 101, 103, such that the diamond die 104 is attached on top of the corresponding IC die 204b on the wafer assembly 201. The resulting bonded wafer assembly 200 may then be annealed at a relatively low temperature (e.g., about 200° C. for about two hours) to enhance the strength of the bond.

In FIG. 2C, the bonded wafer assembly 200 is then diced to singulate the individual IC assembly units 200a-d. In particular, the respective IC assemblies 200a-d include a stack of IC dies 202a-d, 204a-d, including a base IC die 202a-d (e.g., singulated from the base IC wafer 202) and another IC die 204a-d on top of the base die 202a-d (e.g., one of the singulated dies 204a-d attached on top of the base IC wafer 202), along with a dielectric layer 101 on the top die 204a-d. In addition, one of the IC assemblies 200b includes a diamond die 104 attached to the top IC die 204b via the fusion-bonded dielectric layers 101, 103. In this manner, the diamond die 104 serves as a heat spreader to dissipate hot spots that develop on the stacked IC dies 202b, 204b of IC assembly 200b.

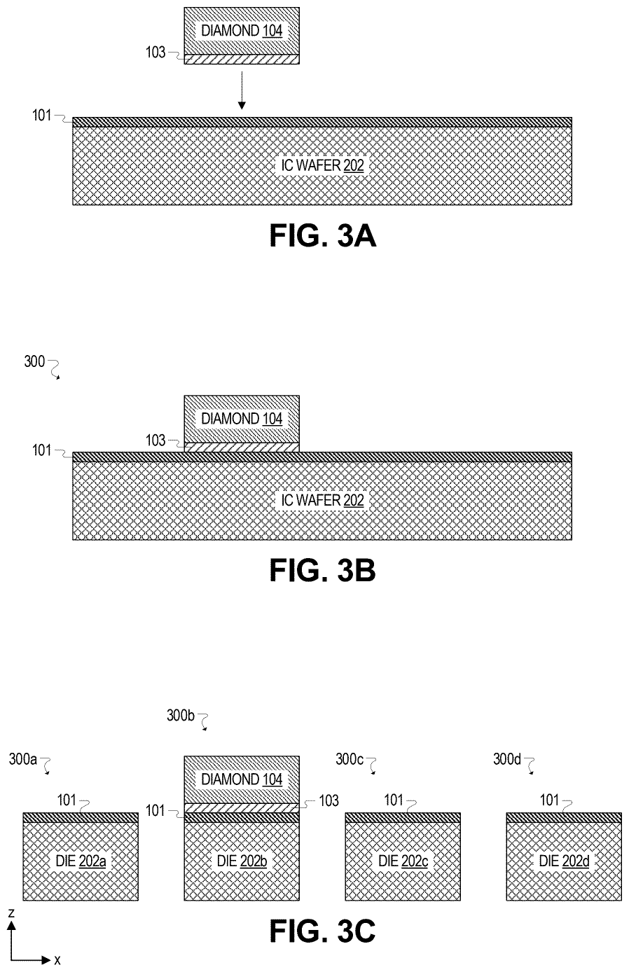

FIGS. 3A-C illustrate an example process flow for die-to-wafer fusion bonding of diamond to integrated circuitry. In the illustrated example, FIGS. 3A-C show cross-section (x-z plane) views from various steps of the process flow.

In FIG. 3A, a base integrated circuit (IC) wafer 202 and a diamond die 104 are received, their dielectric surfaces 101, 103 are cleaned and activated, and the diamond die 104 is placed on top of the base IC wafer 202.

In particular, the base IC wafer 202 is a processed semiconductor wafer with multiple unsingulated IC dies (not shown). Moreover, the base IC wafer 202 and the diamond die 104 each include a dielectric layer 101, 103 on the surface. The dielectric layers 101, 103 on the surface of the base IC wafer 202 and the diamond die 104, respectively, are cleaned and then activated using a plasma activation and hydration treatment. The diamond die 104 is then placed on top of the base IC wafer 202 (e.g., over one of the unsingulated dies in the base IC wafer 202), with their respective dielectric layers 103, 101 in contact with each other.

In FIG. 3B, the plasma-activated dielectric layers 101, 103 on the base IC wafer 202 and the diamond die 104 are fusion bonded to each other at room temperature, thus forming a direct dielectric-to-dielectric bond at the interface between the dielectric layers 101, 103, such that the diamond die 104 is attached on top of one of the unsingulated dies (not shown) in the base IC wafer 202. The resulting bonded wafer assembly 300 may then be annealed at a relatively low temperature (e.g., about 200° C. for about two hours) to enhance the strength of the bond.

In FIG. 3C, the bonded wafer assembly 300 is then diced to singulate the individual IC units 300a-d. In particular, the respective IC units 300a-d include an IC die 202a-d (e.g., singulated from the base IC wafer 202), along with a dielectric layer 101 on top of the die 202a-d. In addition, one of the IC units 300b includes a diamond die 104 attached to the IC die 202b via the fusion-bonded dielectric layers 101, 103. In this manner, the diamond die 104 serves as a heat spreader to dissipate hot spots that develop on the particular IC die 202b during operation.

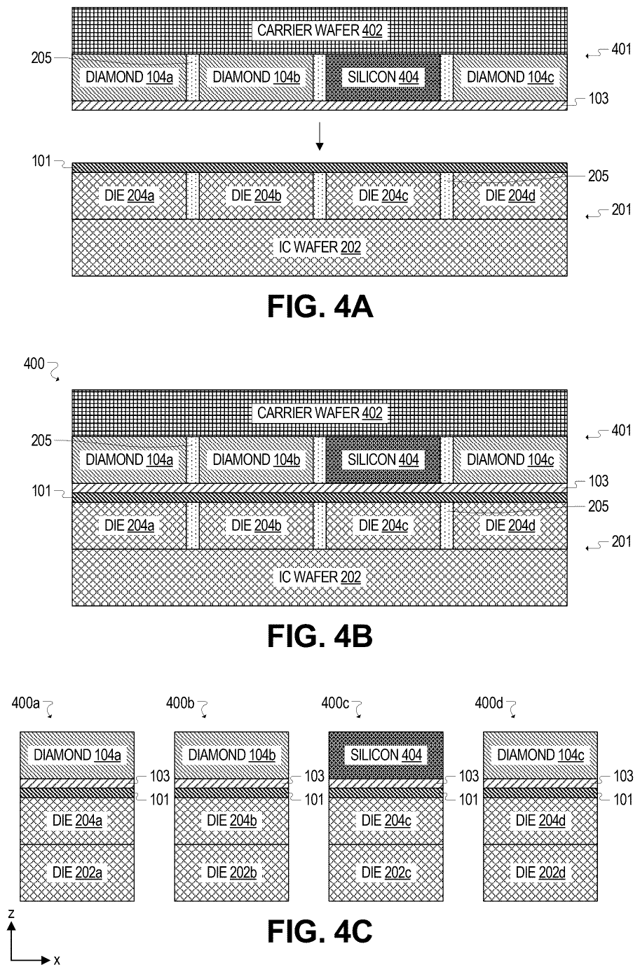

FIGS. 4A-C illustrate an example process flow for wafer-to-wafer fusion bonding of diamond to integrated circuitry. In the illustrated example, FIGS. 4A-C show cross-section (x-z plane) views from various steps of the process flow.

In FIG. 4A, multiple wafer assemblies 201, 401 are received, their dielectric surfaces 101, 103 are cleaned and activated, and one of the wafer assemblies 401 is placed on top of the other wafer assembly 201.

In particular, one of the wafer assemblies 201 includes a base integrated circuit (IC) wafer 202 (e.g., a processed semiconductor wafer with multiple unsingulated IC dies), multiple singulated IC dies 204a-d attached on top of the base IC wafer 202 (e.g., attached to the unsingulated IC dies in the base wafer 202), and dielectric fill 205 in the gaps between the IC dies 204a-d. The wafer assembly 201 also includes a dielectric layer 101 on the surface over the IC dies 204a-d.

The other wafer assembly 401 includes a carrier wafer 402, multiple diamond dies 104a-c and a silicon die 404 attached to the carrier wafer 402, and dielectric fill 205 in the gaps between the dies 104a-c, 404. The wafer assembly 401 also includes a dielectric layer 103 on the surface over the diamond and silicon dies 104a-c, 404.

The dielectric layers 101, 103 on the surface of the respective wafer assemblies 201, 401 are cleaned and then activated using a plasma activation and hydration treatment. One of the wafer assemblies 401 is then placed on top of the other wafer assembly 201—such that the diamond and silicon dies 104a-c, 404 on assembly 401 are aligned over the IC dies 204a-d on assembly 201—with their respective dielectric layers 103, 101 in contact with each other.

In FIG. 4B, the plasma-activated dielectric layers 101, 103 on the wafer assemblies 201, 401 are fusion bonded to each other at room temperature, thus forming a direct dielectric-to-dielectric bond at the interface between the dielectric layers 101, 103, such that the wafer assemblies 201, 401 are attached one on top of the other. The resulting bonded wafer assembly 400 may then be annealed at a relatively low temperature (e.g., about 200° C. for about two hours) to enhance the strength of the bond.

In FIG. 4C, the bonded wafer assembly 400 is then diced to singulate the individual IC assembly units 400a-d. In particular, the respective IC assemblies 400a-d include a stack of IC dies 202a-d, 204a-d, including a base IC die 202a-d (e.g., singulated from the base IC wafer 202) and another IC die 204a-d on top of the base die 202a-d (e.g., one of the singulated dies 204a-d attached on top of the base IC wafer 202). In addition, three of the IC assemblies 400a, b, d include a diamond die 104a-c attached to the top IC die 204a, b, d via fusion-bonded dielectric layers 101, 103, and one of the IC assemblies 400c includes a silicon die 404 attached to the top IC die 204c via fusion-bonded dielectric layers 101, 103. In this manner, the diamond and silicon dies 104a-c, 404 serve as heat spreaders to dissipate hot spots that develop on the stack of IC dies 202a-d, 204a-d during operation.

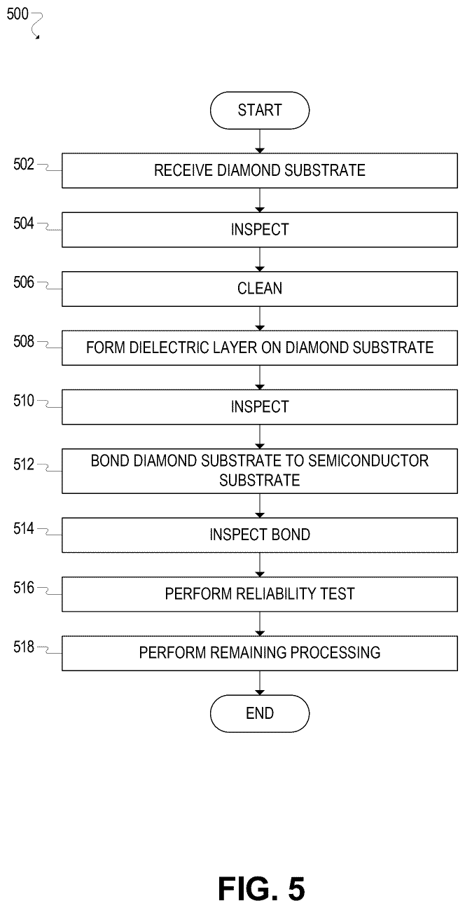

FIG. 5 illustrates a flowchart 500 for fusion bonding a diamond substrate to a semiconductor substrate using dielectric film. In some embodiments, the illustrated process flow may be used to form the example microelectronic assemblies 100, 200a-d, 300a-d, 400a-d, 600 shown and described throughout this disclosure. However, the illustrated process flow is only one example methodology for arriving at the disclosed microelectronic assemblies.

The process flow begins at block 502 by receiving a diamond substrate. In various embodiments, the diamond substrate may be a diamond wafer or a diamond die (e.g., singulated from a diamond wafer).

The process flow then proceeds to block 504 to inspect the diamond substrate. In particular, the diamond substrate may be inspected and characterized for cleanliness, roughness, and flatness. As an example, the diamond substrate may be optically inspected to determine if any foreign material or debris is present on the surface.

The process flow then proceeds to block 506 to clean the diamond substrate. In some embodiments, for example, a water cleaning treatment may be used to clean the diamond substrate and remove any foreign material that may be present on the surface.

The process flow then proceeds to block 508 to form a dielectric layer on the diamond substrate. In some embodiments, for example, dielectric film may be deposited over the diamond substrate to form a thin dielectric layer (e.g., with a thickness of about 50-100 nanometers (nm) in some embodiments) on the diamond substrate. The dielectric film may include any suitable dielectric material, including any of the dielectric materials disclosed herein (e.g., SiN, SiO₂, SiCN, SiC, SiOC, SiON, SiOCN, Al₂O₃, thermal oxides such as thermally-grown SiOₓ), with any applicable level of hydrogenation and any stoichiometric ratio. Moreover, any suitable method of film deposition may be used, including, without limitation, chemical vapor deposition (CVD), physical vapor deposition (e.g., sputtering, electron beam evaporation), and atomic layer deposition (ALD).

In some embodiments, the resulting dielectric layer on the diamond substrate may be controlled to have a surface roughness of less than 0.2 nm to provide a reliable bonding interface. For example, the dielectric layer may be polished or planarized (e.g., using chemical mechanical polishing) to achieve a surface roughness below 0.2 nm. In this manner, the diamond substrate can have a relatively high surface roughness (e.g., 0.5 nm or higher in some cases), as there is no need to planarize or polish the diamond substrate to reduce its surface roughness for bonding purposes, thus reducing costs.

The process flow then proceeds to block 510 to inspect the resulting diamond substrate (and associated dielectric layer). For example, the diamond substrate may be optically inspected to determine if any foreign material is present on the dielectric layer formed over the diamond substrate. If any foreign material is detected, the diamond substrate may undergo another cleaning to remove the foreign material.

The process flow then proceeds to block 512 to bond the diamond substrate to a semiconductor substrate. In some embodiments, for example, the semiconductor substrate may be a processed or unprocessed semiconductor substrate at the die or wafer level, such as an integrated circuit (IC) substrate (e.g., an IC die or die stack, a wafer or carrier with multiple integrated circuit dies), an unprocessed silicon substrate, etc. Moreover, the surface of the semiconductor substrate may include a dielectric layer (e.g., made of any of the dielectric materials disclosed herein), or alternatively, a dielectric layer may be formed on the surface of the semiconductor substrate. In this manner, the respective dielectric layers on the diamond substrate and the semiconductor substrate can be fusion bonded together, thus attaching the diamond substrate to the semiconductor substrate.

In some embodiments, for example, plasma-enhanced bonding may be used to fusion bond the respective dielectric layers on the substrates directly to each other. For example, plasma activation and a hydration process may be used to activate the surface of the respective dielectric layers. The activated dielectric layers on the diamond substrate and the semiconductor substrate can then be bonded together at room temperature to form a dielectric-to-dielectric fusion bond, thus attaching the diamond substrate to the semiconductor substrate. The bonded substrates may then be annealed at a relatively low temperature (e.g., 200° C. for two hours) to increase the bond energy. In this manner, a void-free bond interface may be achieved between the respective dielectric layers with a bond energy of more than 2.0 joules per square meter (J/m²).

The process flow then proceeds to block 514 to inspect the bond between the diamond substrate and the semiconductor substrate. In some embodiments, for example, the bonded interface may be inspected using confocal scanning acoustic microscopy (CSAM) imaging or other similar imaging techniques. In particular, the bonded interface may be inspected for defects, such as delamination associated with local particles, bond wave discontinuation, etc.

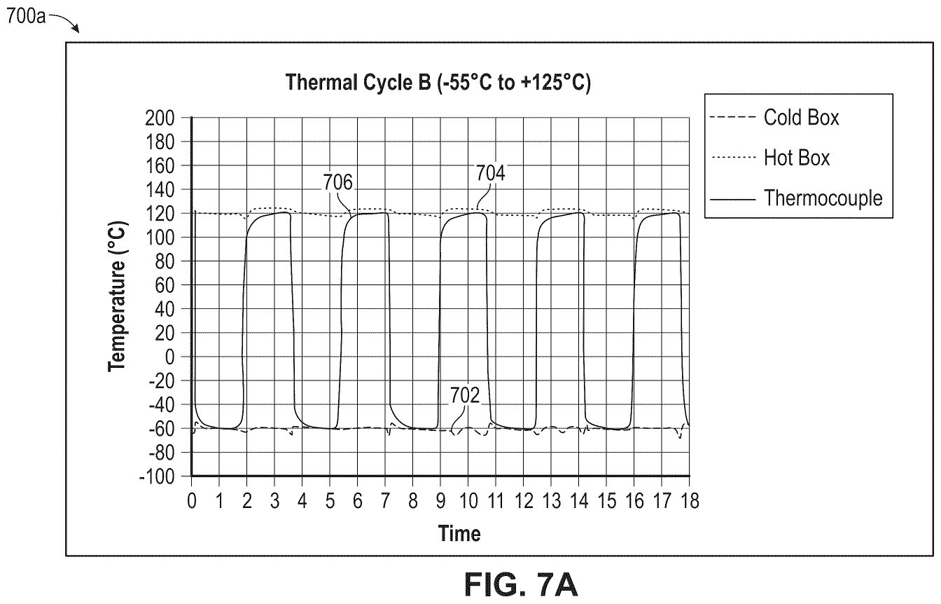

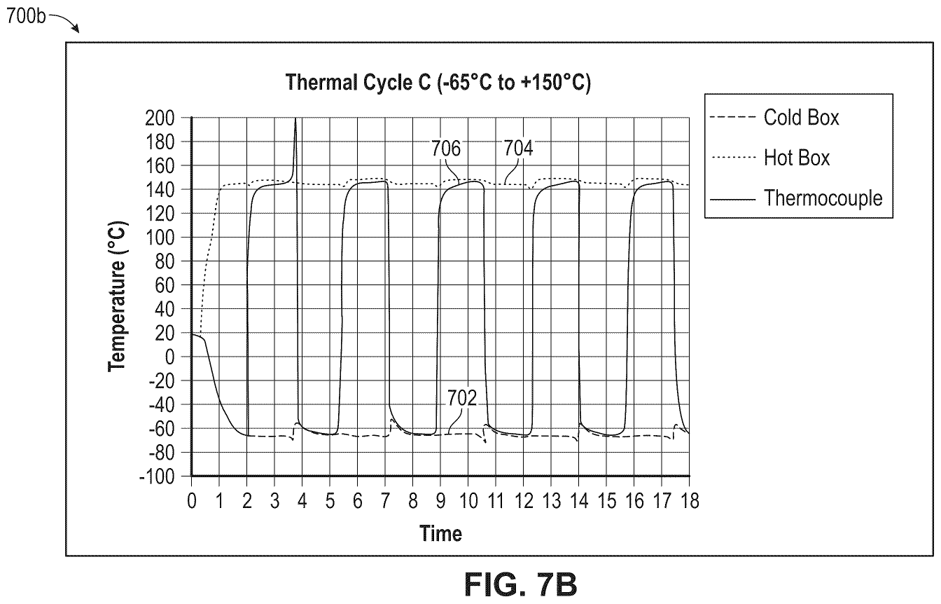

The process flow then proceeds to block 516 to perform a reliability test on the bonded substrate assembly. In some embodiments, for example, the bonded assembly may be subjected to thermal cycling tests to assess the integrity of the bond and ensure no delamination (e.g., die flyout) occurs during or after the thermal cycling process. Examples of thermal cycling tests are shown and described further in connection with FIGS. 7A-B.

The process flow then proceeds to block 518 to perform any remaining processing. For example, in wafer-level or panel-level process flows, the resulting wafer or panel assembly may include multiple repeating units, or chips, with one or more integrated circuit (IC) dies and diamond substrates, and the wafer or panel assembly may be diced to singulate the individual chips. The singulated chips may then be attached to, or assembled in, an interposer, an IC package, a printed circuit board (PCB), and/or an electronic device or system (e.g., system 600, electronic device 1100), among other examples. In some embodiments, for example, the chip may be attached and conductively coupled to an interposer (e.g., via interconnect bumps on the backside of the chip), the interposer may be attached and conductively coupled to a package substrate, and/or the package substrate may be attached and conductively coupled to a PCB.

At this point, the process flow may be complete. In some embodiments, however, the process flow may restart and/or certain blocks may be repeated. For example, in some embodiments, the process flow may restart at block 502 to continue fusion bonding diamond substrates to semiconductor substrates using dielectric film.

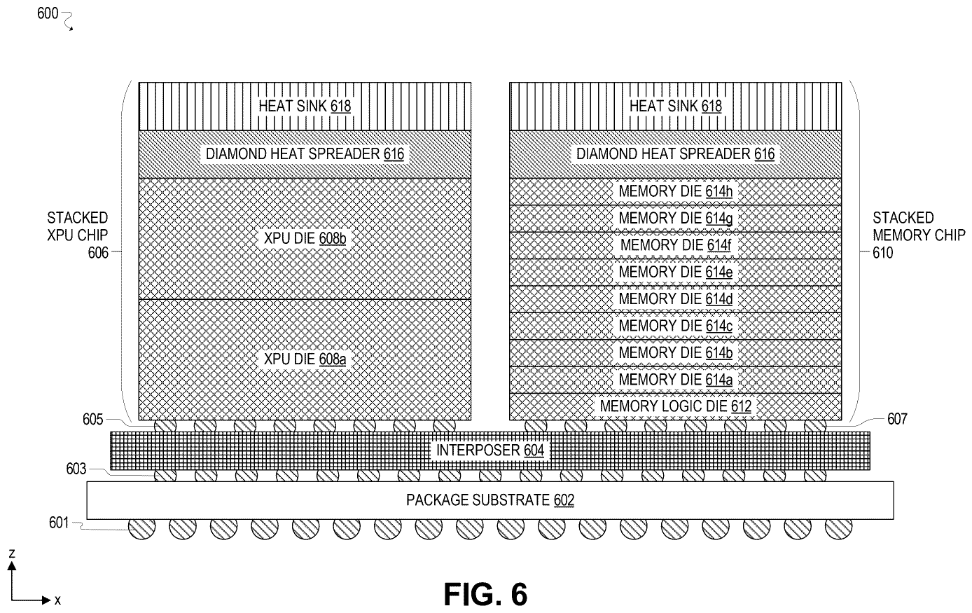

FIG. 6 illustrates a cross-section (x-z plane) view of an example system 600 with fusion-bonded diamond heat spreaders 616. In the illustrated embodiment, system 600 includes a stacked XPU chip 606 and an associated stacked memory chip 610. The stacked XPU chip 606 includes multiple XPU dies 608a-b stacked on top of each other (e.g., vertically integrated). The stacked memory chip 610 includes a base memory logic die 612 and multiple memory dies 614a-h, which are similarly stacked on top of each other (e.g., vertically integrated). Moreover, the stacked XPU chip 606 and the stacked memory chip 610 each include a diamond heat spreader 616 and a heat sink 618 (e.g., a copper heat sink), which are stacked on top of the XPU dies 608a-b and the memory dies 614a-h, respectively. In this manner, when the stacked XPU chip 606 and the stacked memory chip 610 develop hot spots during operation, the diamond heat spreader 616 efficiently spreads heat from the hot spots to the heat sink 618, where the heat is then dissipated.

In some embodiments, the diamond heat spreaders 616 may be fusion bonded to the stacked XPU chip 606 and the stacked memory chip 610 using the embodiments described throughout this disclosure. For example, the diamond heat spreaders 616 may include a diamond substrate with a thin dielectric layer (not shown) on the surface, which may be fusion bonded to a dielectric layer (not shown) on the surface of the top die 608b, 614h in the stacked XPU chip 606 and the stacked memory chip 610, as described throughout this disclosure. In this manner, the diamond substrates are thermally coupled to the dies 608, 614, such that the diamond substrates spread heat generated by the dies 608, 614 during operation.

In the illustrated embodiment, the stacked XPU chip 606 and the stacked memory chip 610 are attached and conductively coupled to an interposer 604 via respective bump interconnects 605, 607 (e.g., conductive bumps/microbumps) in close proximity to each other. In turn, the interposer 604 is attached and conductively coupled to a package substrate 602 via another bump interconnect 603. The package substrate 602 includes another bump interconnect 601 on the backside, which is used to conductively couple the system 600 to another component (not shown). In some embodiments, for example, the backside of the package substrate 602 may be conductively coupled to a printed circuit board (PCB) via bump interconnect 601.

The stacked memory chip 610 includes a base memory logic die 612 and a stack of memory dies 614a-h. The memory logic die 612 may include logic circuitry to manage access to memory on the respective memory dies 614a-h, and the respective memory dies 614a-h may include memory circuitry. In some embodiments, for example, the stacked memory chip 610 may be a high-bandwidth memory (HBM) chip or HBM stack, and the memory dies 614a-h may include dynamic random access memory (DRAM).

The XPUs 608a-b may include any type or combination of processing circuitry (e.g., which may use the stacked memory chip 610 to read/write data). For example, the XPUs 608a-b may include any type or combination of processing units or other computing components, including, but not limited to, microcontrollers, microprocessors, processor cores, central processing units (CPUs), graphics processing units (GPUs), vision processing units (VPUs), neural processing units (NPUs), tensor processing units (TPUs), application-specific integrated circuits (ASICs), and field-programmable gate arrays (FPGAs). The XPU dies 608a-b may also be referred to as an XPU, processing unit, processor die, processor, processing circuitry, compute unit, compute die, and variations thereof.

The interposer 604 may include a substrate with conductive traces and vias, which collectively form electrical connections that conductively couple the XPU dies 608a-b and the stacked memory chip 610 to each other and to the package substrate 602.

System 600 may also be referred to as an electronic device, an integrated circuit (IC), an IC package, a microelectronic assembly, and variations thereof. In some embodiments, system 600 may be part of an electronic device or system, such as a mobile device, a wearable device, a computer, a server, a video playback device, a video game console, a display device, a camera, or an appliance.

It should be appreciated that system 600 is merely shown as an example and numerous variations and alternative embodiments are also within the scope of this disclosure. In various embodiments, for example, certain elements of system 600 may be modified, replaced, rearranged, omitted, and/or added. As an example, system 600 may include any number of chips 606, 610 with diamond substrates or layers 616 for thermal management, and each chip 606, 610 may include any number of dies (e.g., XPU dies 606a-b, memory dies 614a-h, etc.). In some embodiments, the diamond substrates 616 may additionally or alternatively be used as heat sinks or other thermal management components. System 600 may use any interconnect technology for the respective interconnects 601, 603, 605, 607. System 600 may also include other components (not shown), such as cooling components (e.g., heat pipes, vapor chambers, cold plates) to cool the respective chips 606, 610, network interfaces, storage devices, etc.

FIGS. 7A-B illustrate graphs 700a, b of thermal cycling tests performed on a device with a fusion-bonded diamond substrate. In particular, the device under test (DUT) included a diamond substrate bonded to a silicon die (e.g., similar to the microelectronic assemblies 100, 200a-d, 300a-d, 400a-d, 600 described throughout this disclosure). FIG. 7A shows a graph 700a of a thermal cycle B test performed on the DUT, and FIG. 7B shows a graph 700b of a thermal cycle C test performed on the DUT. Thermal cycles B and C are standardized tests used to evaluate the reliability and durability of electronic devices under repeated temperature changes. In these examples, the thermal cycling tests were performed to assess the integrity of the diamond-silicon bond in the DUT.

In particular, a thermocouple 706 (e.g., a temperature-sensing device used to monitor and record the temperature of a sample during thermal cycling) was attached to the diamond substrate on the DUT, and the DUT was repeatedly moved between a cold box 702 and a hot box 704 (e.g., two chambers with low and high temperatures, respectively). In thermal cycle B 700a, the temperature range of the cold/hot boxes 702, 704 was −55° C. to +125° C. In thermal cycle C 700b, the temperature range of the cold/hot boxes 702, 704 was −65° C. to +150° C.

For each test 700a, b, the temperature is shown for the cold box 702, the hot box 704, and the thermocouple 706 as the DUT transitions between the cold/hot boxes 702, 704 over time. In particular, the DUT transitioned between the cold/hot boxes 702, 704 five times, or for five cycles, over time intervals 0-18 (e.g., approximately 8-minute intervals). As shown in graphs 700a, b, the temperature of the thermocouple 706 similarly transitioned between the respective temperatures of the cold/hot boxes 702, 704 for all five cycles. This demonstrates that the diamond substrate remained attached to the DUT throughout the tests, which means the bond between the diamond substrate and the silicon die remained intact.

### Example Integrated Circuit Embodiments

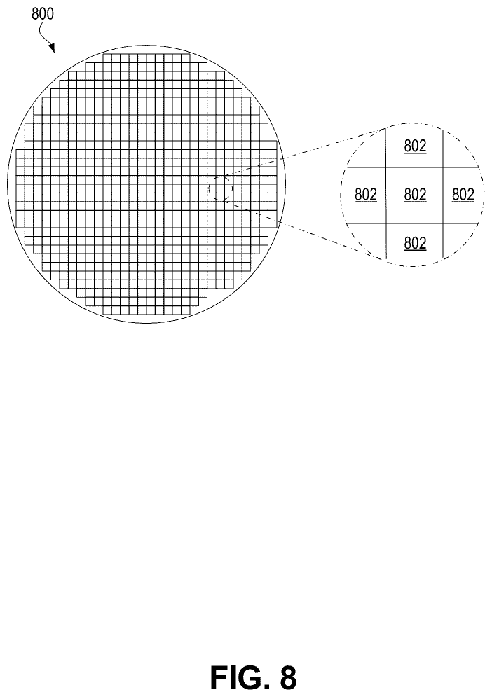

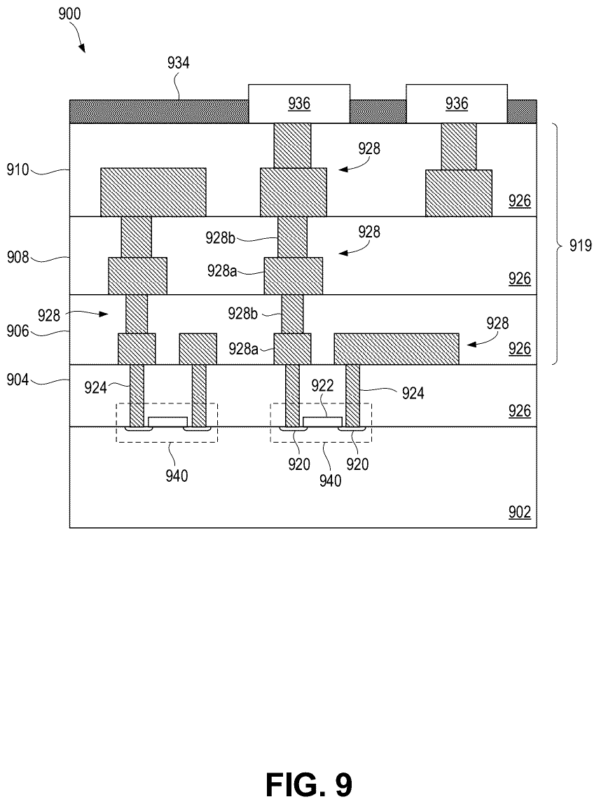

FIG. 8 illustrates a top view of a wafer 800 and dies 802 that may be included in any of the embodiments disclosed herein (e.g., as any suitable ones of the dies 102, 104, 200a-d, 202a-d, 204a-d, 300a-d, 400a-d, 602, 604, 608a-b, 612, 614a-h, 616). The wafer 800 may be composed of semiconductor material and dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The dies 802 may be any of the dies disclosed herein. The dies 802 may include one or more transistors (e.g., transistors 940 of FIG. 9, discussed below), supporting circuitry to route electrical signals to the transistors, passive components (e.g., signal traces, resistors, capacitors, or inductors), and/or any other integrated circuit components that can be fabricated on the wafer. In some embodiments, the wafer 800 or the dies 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), logic gates (e.g., AND, OR, NAND, and NOR gates), or any other suitable circuit element. Multiple ones of these devices and components may be combined on a single die. For example, a memory array formed by multiple memory devices may be formed on the same die as a processor unit or other logic configured to store information in the memory devices or execute instructions stored in the memory array. Some of the embodiments disclosed herein may be manufactured using a die-to-wafer assembly technique in which some dies are attached to a wafer 800 that includes others of the dies, and the wafer 800 is subsequently singulated. Alternatively, or additionally, some of the embodiments disclosed herein may be manufactured using a wafer-to-wafer assembly technique in which multiple wafers 800 with dies 802 are stacked and attached together, and the stack of wafers 800 is subsequently singulated.

FIG. 9 illustrates a cross-sectional view of an integrated circuit structure 900 that may be included in any of the embodiments disclosed herein (e.g., in any of the dies 102, 202a-d, 204a-d, 608a-b, 612, 614a-h, 802). Multiple instances of the integrated circuit structure 900 may be included in the dies 802 (FIG. 8). The integrated circuit structure 900 may be formed on a die substrate 902. The die substrate 902 may be a semiconductor substrate composed of semiconductor material including, for example, n-type or p-type materials (or a combination of both). The die substrate 902 may include, for example, a crystalline substrate formed using a bulk silicon or a silicon-on-insulator (SOI) substructure. In some embodiments, the die substrate 902 can comprise a layer of silicon on top of an SOI layer with bulk silicon below the SOI layer. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit structure 900 may be used. The die substrate 902 may be part of a singulated die (e.g., dies 802 of FIG. 8) or a wafer (e.g., wafer 800 of FIG. 8).

The integrated circuit structure 900 may include device layer 904 disposed on the die substrate 902. The device layer 904 may include features of transistors 940 (e.g., metal oxide semiconductor field-effect transistors (MOSFETs)) formed on the die substrate 902. The transistors 940 may include, for example, source and drain regions (S/D regions 920), a gate 922 to control current flow between the S/D regions 920, and S/D contacts 924 to route electrical signals to and from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, non-planar transistors, or a combination of planar and non-planar transistors. Non-planar transistors may include FinFET transistors, such as double-gate transistors or tri-gate transistors, and wrap-around or all-around gate transistors, such as nanoribbon, nanosheet, or nanowire transistors.

Transistors 940 may include a gate 922 formed of at least two layers, a gate dielectric, and a gate electrode. The gate dielectric may include one or more layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For PMOS transistors, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For NMOS transistors, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, such as a FinFET, the gate electrode may have an upside-down U-shape that includes a top portion substantially parallel to the surface of the die substrate 902 and two side portions that are substantially perpendicular to the top surface of the die substrate 902. In other embodiments, such as a planar FET, at least one of the metal layers that form the gate electrode may be a planar layer that is substantially parallel to the top surface of the die substrate 902 without side portions. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack (comprising the gate dielectric and the gate electrode) to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of sidewall spacer pairs may be used; for instance, two pairs, three pairs, or four pairs of sidewall spacers may be formed on opposing sides of the gate stack.

The S/D regions 920 may be formed within the die substrate 902 adjacent to the gate 922 of transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse further into the die substrate 902 may follow the ion implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or information-carrying signals (e.g., input/output (I/O) signals, may be routed to and/or from devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with interconnect structures 928 of the interconnect layers 906-910. The one or more interconnect layers 906-910 may form a metallization stack 919 (which can also be referred to as an “ILD stack” (inter-layer dielectric stack)) of the integrated circuit structure 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit structures having more or fewer interconnect layers than depicted.

In some embodiments, the interconnect structures 928 may include traces or lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, lines 928a of different interconnect layers 906-910 are electrically coupled by vias 928b.

The interconnect layers 906-910 may include a dielectric material 926 within which the interconnect structures 928 are disposed, as shown in FIG. 9. In some embodiments, dielectric material 926 in different ones of the interconnect layers 906-910 may have different compositions; in other embodiments, the composition of the dielectric material 926 between different interconnect layers 906-910 may be the same. The device layer 904 may include a dielectric material 926 within which the transistors 940 are disposed and upon which a bottom layer of the metallization stack is located. The dielectric material 926 that is part of the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (which can be referred to as a Metal 1 or “M1” layer) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (which can be referred to as a Metal 2 or “M2” layer) may be formed directly on the first interconnect layer 906. In some embodiments, the second interconnect layer 908 may include vias 928b to couple the lines 928a of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (which can be referred to as a Metal 3 or “M3” layer) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit structure 900 (i.e., farther away from the device layer 904) may be thicker than the interconnect layers that are lower in the metallization stack 919, with lines 928a and vias 928b in the higher interconnect layers being thicker than those in the lower interconnect layers.

The integrated circuit structure 900 may include a solder resist material 934 (e.g., polyimide or similar material) and conductive contacts 936 formed on the stack of interconnect layers 906-910. In FIG. 9, the conductive contacts 936 are illustrated as taking the form of bond pads. The conductive contacts 936 may be electrically coupled with interconnect structures 928 of the top-most layer in the metallization stack 919 and configured to route electrical signals between the transistors 940 and components external to the integrated circuit structure 900. For example, solder bonds may be formed on the conductive contacts 936 to mechanically and/or electrically couple an integrated circuit component comprising the integrated circuit structure 900 with another component (e.g., a printed circuit board). The integrated circuit structure 900 may include additional or alternate structures to route electrical signals from the interconnect layers 906-910; for example, the conductive contacts 936 may include other analogous features (e.g., posts) that can route the electrical signals between the transistors 940 and external components.

In some embodiments in which the integrated circuit structure 900 is part of a double-sided die, the integrated circuit structure 900 may include a second metallization stack (not shown) located on the opposite side of the die substrate 902 from the device layer 904. This second metallization stack may include multiple interconnect layers as discussed above with reference to the interconnect layers 906-910. Through-silicon vias (TSVs) that extend through the die substrate 902 can provide electrically conductive pathways from the transistors 940 to the second metallization stack and the second metallization stack can electrically couple the TSVs to additional conductive contacts (not shown) located on the opposite side of the integrated circuit structure 900 from the conductive contacts 936.

In some embodiments, TSVs extending through the die substrate 902 can be used for routing power and ground signals from conductive contacts located on the opposite side of the integrated circuit structure 900 from the conductive contacts 936 to the transistors 940 and any other components integrated into the integrated circuit structure 900, and the metallization stack 919 can be used to route information-carrying signals from the conductive contacts 936 to transistors 940 and any other components integrated into the integrated circuit structure 900. Put another way, the routing of power and ground signals to the transistors 940 can be separated (via a back-side or bottom-side metallizaton stack and TSVs) from the routing of information-carrying signals to the transistors. The power and ground signals are provided by a backside or bottom-side metallization stack and TSVs, and information-carrying signals are provided by a topside metallization stack (e.g., metallization stack 919).

Several integrated circuit dies may be stacked with one or more TSVs in the individual stacked dies providing connection between one of the dies to any of the other dies in the stack. For example, one or more high-bandwidth memory (HBM) integrated circuit dies can be stacked on top of a base integrated circuit die and TSVs in the HBM dies can provide connection between the individual HBM dies and the base integrated circuit die. Conductive contacts can provide additional connections between adjacent integrated circuit dies in the stack. In some embodiments, the conductive contacts can be fine-pitch solder bumps (microbumps).

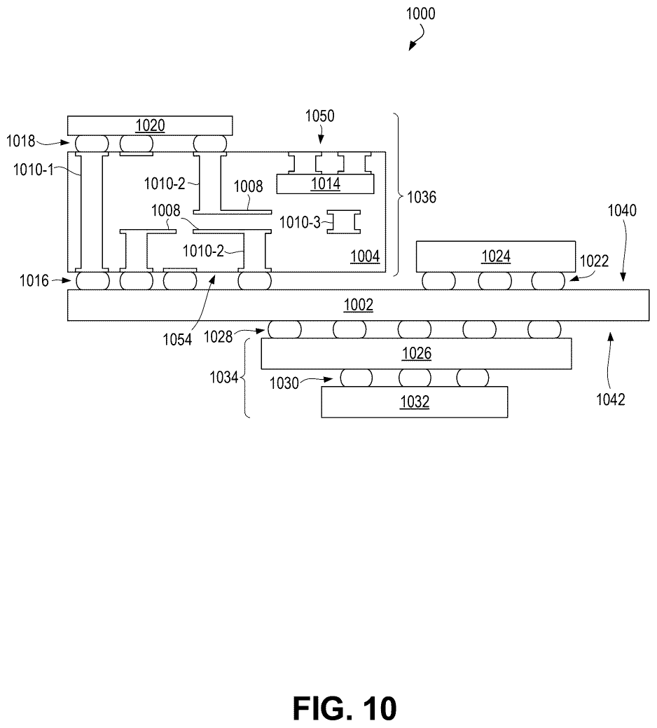

FIG. 10 illustrates a cross-sectional view of an integrated circuit device assembly 1000 that may include any of the embodiments disclosed herein. In some embodiments, for example, the embedded devices 1014 and/or IC components 1020, 1024, 1026, 1032 of the integrated circuit device assembly 1000 may include a diamond substrate bonded to an integrated circuit die. In some embodiments, the integrated circuit device assembly 1000 may be a microelectronic assembly. The integrated circuit device assembly 1000 includes a number of components disposed on a circuit board 1002 (which may be a motherboard, system board, mainboard, etc.). The integrated circuit device assembly 1000 includes components disposed on a first face 1040 of the circuit board 1002 and a second face 1042 of the circuit board 1002, the second face 1042 opposing the first face 1040. Generally, components may be disposed on either or both of the first face 1040 and the second face 1042 of the circuit board 1002. Any of the integrated circuit components discussed below with reference to the integrated circuit device assembly 1000 may take the form of any suitable ones of the embodiments of the microelectronic assemblies 100, 200a-d, 300a-d, 400a-d, 600 disclosed herein.

In some embodiments, the circuit board 1002 may be a printed circuit board (PCB) including multiple metal (or interconnect) layers separated from one another by layers of dielectric material and interconnected by electrically conductive vias. The individual metal layers comprise conductive traces. The metal layers may be formed in a desired pattern to route electrical signals between the components electrically coupled to the circuit board 1002. In other embodiments, the circuit board 1002 may be a non-PCB substrate (e.g., a package substrate or an interposer).

The integrated circuit device assembly 1000 illustrated in FIG. 10 includes a package-on-interposer structure 1036 coupled to the first face 1040 of the circuit board 1002 by coupling components 1016. The coupling components 1016 may electrically and mechanically couple the package-on-interposer structure 1036 to the circuit board 1002 and may include solder balls (as shown in FIG. 10), pins (e.g., as part of a pin grid array (PGA), contacts (e.g., as part of a land grid array (LGA)), hybrid bond interconnect (HBI) pads, male and female portions of a socket, an adhesive, an underfill material, and/or any other suitable electrical and/or mechanical coupling structure (e.g., a conductive contact). The coupling components 1016 may serve as the coupling components illustrated or described for any substrate assembly or substrate assembly components described herein (e.g., integrated circuit components), as appropriate.

The package-on-interposer structure 1036 may include an integrated circuit component 1020 coupled to an interposer 1004. The interposer 1004 may provide an intervening substrate used to bridge the circuit board 1002 and the integrated circuit component 1020. The integrated circuit component 1020 is coupled to the interposer 1004 by coupling components 1018. The coupling components 1018 may take any suitable form, such as the forms discussed above with reference to the coupling components 1016. Although FIG. 10 shows just one integrated circuit component attached to the interposer, multiple integrated circuit components may be coupled to the interposer 1004. Additional interposers may be coupled to the interposer 1004.

The integrated circuit component 1020 may be a packaged or unpackaged integrated circuit product that includes one or more integrated circuit dies (e.g., the die 802 of FIG. 8, a die comprising the integrated circuit structure 900 of FIG. 9) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one unpackaged example of an integrated circuit component 1020, a single monolithic integrated circuit die comprises solder bumps attached to contacts on the die. The solder bumps allow the die to be directly attached to the interposer 1004. The integrated circuit component 1020 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1020 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1020 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1020 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1004 may spread connections to a wider or narrower pitch or reroute a connection to a different connection. For example, the interposer 1004 may couple coupling components 1018 having a first pitch to coupling components 1016 having a wider pitch than the first pitch. In the embodiment illustrated in FIG. 10, the integrated circuit component 1020 and the circuit board 1002 are attached to opposing sides of the interposer 1004. In other embodiments, the integrated circuit component 1020 and the circuit board 1002 may be attached to a same side of the interposer 1004. In some embodiments, three or more components may be interconnected by way of the interposer 1004.

In some embodiments, the interposer 1004 may be formed as a PCB, including multiple metal layers separated from one another by layers of dielectric material and interconnected by electrically conductive vias. In some embodiments, the interposer 1004 may be formed of an epoxy resin, a fiberglass-reinforced epoxy resin, an epoxy resin with inorganic fillers, a ceramic material, or a polymer material such as polyimide. In some embodiments, the interposer 1004 may be formed of alternate rigid or flexible materials that may include the same materials described above for use in a semiconductor substrate, such as silicon, germanium, and other group III-V and group IV materials. The interposer 1004 may include metal interconnects 1008 and vias, including but not limited to through hole vias 1010-1 (that extend from a first face 1050 of the interposer 1004 to a second face 1054 of the interposer 1004), blind vias 1010-2 (that extend from the first face 1050 or the second face 1054 of the interposer 1004 to an internal metal layer), and buried vias 1010-3 (that connect internal metal layers).

In some embodiments, the interposer 1004 can comprise a silicon interposer. Through silicon vias (TSV) extending through the silicon interposer can connect connections on a first face of a silicon interposer to an opposing second face of the silicon interposer. In some embodiments, an interposer 1004 comprising a silicon interposer can further comprise one or more routing layers to route connections on a first face of the interposer 1004 to an opposing second face of the interposer 1004.

In some embodiments, certain components of assembly 1000 (e.g., interposer 1004, circuit board 1002, IC components 1020, 1024, 1026, 1032) may include an amorphous solid layer of glass (which can be referred to a glass core or glass substrate). In some embodiments, the layer of glass can comprise silica (comprising silicon dioxide (SiO₂)), fused silica, aluminosilicate (comprising aluminum oxide (Al₂O₃) and silicon dioxide), borosilicate (comprising silicon dioxide and boron trioxide (B₂O₃)), or alumino-borosilicate (comprising aluminum oxide, silicon dioxide, and boron trioxide). In some embodiments, the layer of glass can comprise one or more of the following additives: aluminum oxide, boron trioxide, magnesium oxide (MgO), calcium oxide (CaO), strontium oxide (SrO), barium oxide (BaO), tin(IV) oxide (SnO₂), nitrous oxide (Na₂O), potassium oxide (K₂O), diphosphorous trioxide (P₂O₃), zirconium dioxide (ZrO₂), lithium oxide (Li₂°), titanium, and zinc. In some embodiments, the layer of glass can comprise silicon and oxygen, as well as one or more of aluminum, boron, magnesium, calcium, barium, tin, sodium, potassium, strontium, phosphorous, zirconium, lithium, titanium, and zinc. In some embodiments, the layer of glass comprises at least 23 percent silicon by weight, at least 26 percent oxygen by weight, and at least five percent aluminum by weight. In some embodiments, the layer of glass does not include an organic adhesive or an organic material. For example, the layer of glass is not a substrate or a board comprising glass fibers and an epoxy binder, such as a printed circuit board (PCB) comprising multiple metal (or interconnect) layers separated from one another by layers of dielectric material (e.g., FR-4 or other fiberglass-reinforced epoxy laminate) and interconnected by electrically conductive vias.

In some embodiments, the glass layer has a thickness in the range of about 50 microns to about 1.4 millimeters. In some embodiments, the glass layer is or is part of a multi-layer glass substrate (a coreless substrate). Individual glass layers in a multi-layer glass substrate can have a thickness in the range of about 25 microns to about 50 microns. In some embodiments, a glass layer can have a length in the range of about 10 millimeters to about 250 millimeters on a side (e.g., can have an area in the range of about 10 mm×10 mm to about 250 mm×250 mm). In some embodiments, the glass layer comprises a rectangular prism volume with sections or portions (e.g., through-glass vias) removed and filled with other metals (e.g., metal).

In some embodiments, redistribution layers (RDL) can be located on either or both sides of the glass layer to provide electrically conductive paths from top and/or bottom surfaces of the interposer 1004 or circuit board 1002 to the glass layer. The glass layer can comprise through-glass vias (TGVs) that extend through the glass layer to provide electrically conductive paths through the glass core, glass substrate, or glass layer.

The interposer 1004 may further include embedded devices 1014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1004. The package-on-interposer structure 1036 may take the form of any of the package-on-interposer structures known in the art.

The integrated circuit device assembly 1000 may include an integrated circuit component 1024 coupled to the first face 1040 of the circuit board 1002 by coupling components 1022. The coupling components 1022 may take the form of any of the embodiments discussed above with reference to the coupling components 1016, and the integrated circuit component 1024 may take the form of any of the embodiments discussed above with reference to the integrated circuit component 1020.

The integrated circuit device assembly 1000 illustrated in FIG. 10 further includes a package-on-package structure 1034 coupled to the second face 1042 of the circuit board 1002 by coupling components 1028. The package-on-package structure 1034 may include an integrated circuit component 1026 and an integrated circuit component 1032 coupled together by coupling components 1030 such that the integrated circuit component 1026 is disposed between the circuit board 1002 and the integrated circuit component 1032. The coupling components 1028 and 1030 may take the form of any of the embodiments of the coupling components 1016 discussed above, and the integrated circuit components 1026 and 1032 may take the form of any of the embodiments of the integrated circuit component 1020 discussed above. The package-on-package structure 1034 may be configured in accordance with any of the package-on-package structures known in the art.

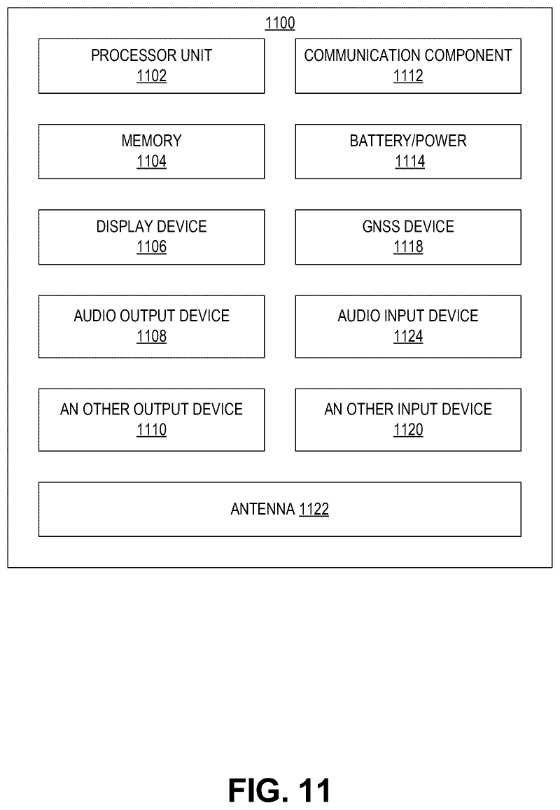

FIG. 11 illustrates a block diagram of an example electrical device 1100 that may include any of the embodiments disclosed herein. For example, any suitable ones of the components of the electrical device 1100 may include one or more of the integrated circuits 102, 202a-d, 204a-d, 608a-b, 612, 614a-h with attached diamond substrates 104, 616, integrated circuit device assembly 1000, integrated circuit component 1020, integrated circuit structure 900, or integrated circuit dies 802 disclosed herein, and may be arranged in any of the microelectronic assemblies 100, 200a-d, 300a-d, 400a-d, 600 disclosed herein. A number of components are illustrated in FIG. 11 as included in the electrical device 1100, but any one or more of these components may be omitted or duplicated, as suitable for the application. In some embodiments, some or all of the components included in the electrical device 1100 may be attached to one or more motherboards mainboards, or system boards. In some embodiments, one or more of these components are fabricated onto a single system-on-a-chip (SoC) die.

Additionally, in various embodiments, the electrical device 1100 may not include one or more of the components illustrated in FIG. 11, but the electrical device 1100 may include interface circuitry for coupling to the one or more components. For example, the electrical device 1100 may not include a display device 1106, but may include display device interface circuitry (e.g., a connector and driver circuitry) to which a display device 1106 may be coupled. In another set of examples, the electrical device 1100 may not include an audio input device 1124 or an audio output device 1108, but may include audio input or output device interface circuitry (e.g., connectors and supporting circuitry) to which an audio input device 1124 or audio output device 1108 may be coupled.

The electrical device 1100 may include one or more processor units 1102. As used herein, the terms “processor unit,” “processing unit,” or “processor” may refer to any device or portion of a device that processes electronic data from registers and/or memory to transform that electronic data into other electronic data that may be stored in registers and/or memory. The one or more processor units 1102 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1100 may include a memory 1104, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1104 may include memory that is located on the same integrated circuit die as the one or more processor units 1102. This memory may be used as cache memory (e.g., Level 1 (L1), Level 2 (L2), Level 3 (L3), Level 4 (L4), Last Level Cache (LLC)) and may include embedded dynamic random-access memory (eDRAM) or spin transfer torque magnetic random-access memory (STT-MRAM).

In some embodiments of the electrical device 1100, a first one of the one or more processor units 1102 can be heterogeneous or asymmetric to a second one of the one or more processor units 1102 in the electrical device 1100. There can be a variety of differences between the one or more processor units 1102 in a system in terms of a spectrum of metrics of merit including architectural, microarchitectural, thermal, power consumption characteristics, and the like. These differences can effectively manifest themselves as asymmetry and heterogeneity among the one or more processor units 1102 in the electrical device 1100.

In some embodiments, the electrical device 1100 may include a communication component 1112. For example, the communication component 1112 can manage wireless communications for the transfer of data to and from the electrical device 1100. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1112 may operate in accordance with other wireless protocols in other embodiments. The electrical device 1100 may include an antenna 1122 to facilitate wireless communications and/or to receive other wireless communications (such as AM or FM radio transmissions).

In some embodiments, the communication component 1112 may manage wired communications, such as electrical, optical, or any other suitable communication protocols (e.g., IEEE 802.3 Ethernet standards). In some embodiments, the electrical device 1100 comprises multiple communication components. For instance, a first communication component may be dedicated to shorter-range wireless communications such as Wi-Fi or Bluetooth, and a second communication component may be dedicated to longer-range wireless communications such as global positioning system (GPS), EDGE, GPRS, CDMA, WiMAX, LTE, EV-DO, or others. In some embodiments, a first communication component may be dedicated to wireless communications, and a second communication component may be dedicated to wired communications.

The electrical device 1100 may include battery/power circuitry 1114. The battery/power circuitry 1114 may include one or more energy storage devices (e.g., batteries or capacitors) and/or circuitry for coupling components of the electrical device 1100 to an energy source separate from the electrical device 1100 (e.g., AC line power).

The electrical device 1100 may include a display device 1106 (or corresponding interface circuitry, as discussed above). The display device 1106 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1100 may include an audio output device 1108 (or corresponding interface circuitry, as discussed above). The audio output device 1108 may include any embedded or wired or wirelessly connected external device that generates an audible indicator, such as speakers, headsets, or earbuds.

The electrical device 1100 may include an audio input device 1124 (or corresponding interface circuitry, as discussed above). The audio input device 1124 may include any embedded or wired or wirelessly connected device that generates a signal representative of a sound, such as microphones, microphone arrays, or digital instruments (e.g., instruments having a musical instrument digital interface (MIDI) output). The electrical device 1100 may include a Global Navigation Satellite System device (GNSS) (or corresponding interface circuitry, as discussed above), such as a Global Positioning System (GPS) device. The GNSS device 1118 may be in communication with a satellite-based system and may determine a geolocation of the electrical device 1100 based on information received from one or more GNSS satellites, as known in the art.

The electrical device 1100 may include another output device 1110 (or corresponding interface circuitry, as discussed above). Examples of the other output device 1110 may include an audio codec, a video codec, a printer, a wired or wireless transmitter for providing information to other devices, or an additional storage device.

The electrical device 1100 may include another input device 1120 (or corresponding interface circuitry, as discussed above). Examples of the other input device 1120 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1100 may have any form factor, such as a hand-held or mobile electrical device (e.g., a cell phone, a smartphone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console), a desktop electrical device, a server, a rack-level computing solution (e.g., blade, tray, or sled computing system), a workstation or other networked computing component, a printer, a scanner, a display device (e.g., monitor, television), a set-top box, a video playback device, an entertainment control unit, a stationary gaming console, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1100 may be any other electronic device that processes data. In some embodiments, the electrical device 1100 may comprise multiple discrete physical components. Given the range of devices that the electrical device 1100 can be manifested as in various embodiments, in some embodiments, the electrical device 1100 can be referred to as a computing device or a computing system.

While the concepts of the present disclosure are susceptible to various modifications and alternative forms, specific embodiments thereof have been shown by way of example in the drawings and are described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the drawings. Additionally, the inclusion of a structural or method feature in a particular drawing is not meant to imply that such feature is required in all embodiments and, in some embodiments, such feature may not be included or may be combined with other features. Further, it should be understood that the various embodiments shown in the drawings are illustrative representations and are not necessarily drawn to scale. In some instances, the same or similar reference numerals may be used to designate the same or similar features in different drawings.

The illustrations and/or descriptions of various embodiments may be simplified, approximated, or idealized for ease of understanding, and as a result, they may not necessarily reflect the level of precision nor variation that may be present in actual embodiments. For example, while some drawings generally indicate straight lines, right angles, and smooth surfaces, actual implementations of the disclosed embodiments may have less than perfect straight lines and right angles, and some features may have surface topography or otherwise be non-smooth, given real-world limitations of fabrication processes. Similarly, illustrations and/or descriptions of how components are arranged may be simplified or approximated for ease of understanding and may vary by some margin of error in actual embodiments (e.g., due to fabrication processes, etc.).

As used herein, references to an “embodiment” or “embodiments” may refer to one or more of the same or different embodiments. Some embodiments may have some, all, or none of the features described for other embodiments.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

As used herein, a list of items joined by the phrase “and/or” can mean any combination of the listed items. For example, the phrase “A, B, and/or C” can mean A; B; C; A and B; A and C; B and C; or A, B and C. As used herein, a list of items referenced by the phrase “at least one of” or the phrase “one or more of” can mean any combination of the listed items. For example, the phrase “at least one of A, B, or C” or the phrase “one or more of A, B, or C” can mean A; B; C; A and B; A and C; B and C; or A, B, and C.

The terms “substantially,” “close,” “approximately,” “near,” “about”, and the like may refer to being within +/−10% of a target value unless otherwise specified. Similarly, terms describing spatial relationships, such as “perpendicular,” “orthogonal,” or “coplanar,” may refer to being substantially within the described spatial relationships (e.g., within +/−10 degrees of orthogonality).

Certain terminology may be used in the foregoing description for the purpose of reference only, and thus is not intended to be limiting. For example, terms such as “upper,” “lower,” “above,” “below,” “bottom,” and “top” may refer to directions in the drawings to which reference is made. Terms such as “front,” “back,” “rear,” and “side” may describe the orientation and/or location of portions of a feature within a consistent but arbitrary frame of reference, which may be made clear by reference to the description and drawings associated with that feature. Such terminology may include the words specifically mentioned above, derivatives thereof, and words of similar import.

As used herein, the phrase “located on” in the context of a first feature located on a second feature refers to the first feature being in direct or indirect physical contact with the second feature (e.g., with or without one or more intervening features between the first and second features).

As used herein, the term “adjacent” refers to features that are arranged next to each other (e.g., side by side, top and bottom) with or without one or more intervening features between them.

As used herein, the terms “coupled” and “connected” may refer to a direct or indirect coupling or connection (e.g., with or without one or more intervening elements).

As used herein, the phrase “electrically coupled” refers to the presence of one or more electrically conductive paths between components that are recited as being electrically coupled.

As used herein, the phrase “thermally coupled” refers to components that are coupled to facilitate the transfer of heat.

As used herein, an “integrated circuit” may refer to a packaged or unpackaged integrated circuit product. In one example, a packaged integrated circuit may include one or more integrated circuit dies mounted on a package substrate with the integrated circuit dies and package substrate encapsulated in a casing material, such as a metal, plastic, glass, or ceramic. In one example, a packaged integrated circuit may include one or more processor units mounted on a substrate with an exterior surface of the substrate comprising a solder ball grid array (BGA). In one example of an unpackaged integrated circuit, a single monolithic integrated circuit die may include solder bumps attached to contacts on the die, such that the solder bumps allow the die to be directly attached to a printed circuit board or other substrate. An integrated circuit may include one or more of any computing system component, such as a processor unit (e.g., system-on-a-chip (SoC), processor core, graphics processor unit (GPU), accelerator, chipset processor), input/output (I/O) controller, memory, network interface controller, or any other computing system component described or referenced herein.

The embodiments described herein can be implemented in any integrated circuit (e.g., packaged or unpackaged). In some embodiments, an integrated circuit implemented with the described embodiments may be attached to a printed circuit board. Moreover, in some embodiments, one or more additional components (e.g., other integrated circuits, a battery, an antenna) may also be attached to the printed circuit board. In some embodiments, the printed circuit board and the integrated circuit can be located in a computing device having a housing that encloses the printed circuit board and the integrated circuit.

The described embodiments may be implemented, in some cases, in hardware, firmware, software, or any combination thereof. The disclosed embodiments may also be implemented as instructions carried by or stored on one or more transitory or non-transitory machine-readable (e.g., computer-readable) storage media, which may be read and executed by one or more processors. A machine-readable storage medium may be embodied as any storage device, mechanism, or other physical structure for storing or transmitting information in a form readable by a machine, including volatile or non-volatile memory (e.g., random access memory (RAM), flash memory), hard drives (e.g., hard disk drive (HDD), solid state drive (SSD)), media discs, or combinations thereof.

### EXAMPLES

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 includes a microelectronic assembly, comprising: a semiconductor substrate; a diamond substrate; a first dielectric layer on the semiconductor substrate; and a second dielectric layer on the diamond substrate, wherein the second dielectric layer is bonded to the first dielectric layer.

Example 2 includes the microelectronic assembly of Example 1, wherein: the first dielectric layer comprises silicon and oxygen; and the second dielectric layer comprises (i) silicon and nitrogen or (ii) aluminum and oxygen.

Example 3 includes the microelectronic assembly of Example 1, wherein the first dielectric layer and the second dielectric layer respectively comprise: silicon and nitrogen; silicon and oxygen; silicon, carbon, and nitrogen; silicon and carbon; silicon, oxygen, and carbon; silicon, oxygen, and nitrogen; silicon, oxygen, carbon, and nitrogen; or aluminum and oxygen.

Example 4 includes the microelectronic assembly of any of Examples 1-3, wherein: the first dielectric layer has a thickness in a range of about 50 nanometers to 1 micron; and the second dielectric layer has a thickness in a range of about 50 nanometers to 100 nanometers.

Example 5 includes the microelectronic assembly of any of Examples 1-4, wherein the second dielectric layer is bonded directly to the first dielectric layer.

Example 6 includes the microelectronic assembly of any of Examples 1-5, wherein an interface between the first dielectric layer and the second dielectric layer has a bond energy of more than 2.0 joules per square meter.

Example 7 includes the microelectronic assembly of any of Examples 1-6, wherein an interface between the first dielectric layer and the second dielectric layer has a thermal resistance of less than 0.005 square centimeters kelvin per watt.

Example 8 includes the microelectronic assembly of any of Examples 1-7, wherein the second dielectric layer has a surface roughness of less than 0.2 nanometers.

Example 9 includes the microelectronic assembly of any of Examples 1-8, wherein the diamond substrate has a surface roughness of 0.5 nanometers or higher.

Example 10 includes the microelectronic assembly of any of Examples 1-9, wherein the diamond substrate is thermally coupled to the semiconductor substrate, wherein the diamond substrate is to spread heat produced by the semiconductor substrate.

Example 11 includes the microelectronic assembly of any of Examples 1-10, wherein the diamond substrate is a heat spreader.

Example 12 includes the microelectronic assembly of any of Examples 1-11, wherein the semiconductor substrate comprises an integrated circuit (IC) die.

Example 13 includes the microelectronic assembly of Example 12, wherein: the IC die is a first IC die; and the microelectronic assembly further comprises a second IC die, wherein the second IC die is below the first IC die, and wherein the first IC die is below the diamond substrate.

Example 14 includes the microelectronic assembly of any of Examples 1-13, wherein the semiconductor substrate comprises silicon.

Example 15 includes a microelectronic assembly, comprising: an integrated circuit (IC) die; a first dielectric layer above the IC die; a second dielectric layer above the first dielectric layer, wherein the second dielectric layer is bonded to the first dielectric layer; and a diamond layer above the second dielectric layer.

Example 16 includes a microelectronic assembly, comprising: an integrated circuit (IC) die; a diamond substrate attached to the IC die; and a plurality of dielectric layers between the IC die and the diamond substrate, wherein the plurality of dielectric layers include a first dielectric layer and a second dielectric layer, wherein the first dielectric layer is on the IC die, wherein the second dielectric layer is on the diamond substrate, and wherein the first dielectric layer and the second dielectric layer are bonded together.

Example 17 includes an electronic device, comprising: an integrated circuit, wherein a surface of the integrated circuit comprises a first dielectric layer; and a diamond substrate attached to the integrated circuit, wherein a surface of the diamond substrate comprises a second dielectric layer, wherein the second dielectric layer is bonded directly to the first dielectric layer.

Example 18 includes the electronic device of Example 17, wherein: the first dielectric layer comprises silicon and oxygen; and the second dielectric layer comprises (i) silicon and nitrogen or (ii) aluminum and oxygen.

Example 19 includes the electronic device of Example 17, wherein the first dielectric layer and the second dielectric layer respectively comprise: silicon and nitrogen; silicon and oxygen; silicon, carbon, and nitrogen; silicon and carbon; silicon, oxygen, and carbon; silicon, oxygen, and nitrogen; silicon, oxygen, carbon, and nitrogen; or aluminum and oxygen.

Example 20 includes the electronic device of any of Examples 17-19, wherein: the first dielectric layer has a thickness in a range of about 50 nanometers to 1 micron; and the second dielectric layer has a thickness in a range of about 50 nanometers to 100 nanometers.

Example 21 includes the electronic device of any of Examples 17-20, wherein an interface between the first dielectric layer and the second dielectric layer has a bond energy of more than 2.0 joules per square meter.

Example 22 includes the electronic device of any of Examples 17-21, wherein an interface between the first dielectric layer and the second dielectric layer has a thermal resistance of less than 0.005 square centimeters kelvin per watt.

Example 23 includes the electronic device of any of Examples 17-22, wherein the second dielectric layer has a surface roughness of less than 0.2 nanometers.

Example 24 includes the electronic device of any of Examples 17-23, wherein the diamond substrate has a surface roughness of 0.5 nanometers or higher.

Example 25 includes the electronic device of any of Examples 17-24, further comprising a heat spreader, wherein the heat spreader comprises the diamond substrate.

Example 26 includes the electronic device of any of Examples 17-25, wherein the integrated circuit comprises: an integrated circuit (IC) die; or a plurality of IC dies, wherein the plurality of IC dies are stacked vertically.

Example 27 includes the electronic device of any of Examples 17-26, wherein the integrated circuit comprises processing circuitry or memory circuitry.

Example 28 includes the electronic device of any of Examples 17-27, wherein the integrated circuit comprises a central processing unit, a graphics processing unit, a vision processing unit, a neural processing unit, or a field-programmable gate array.

Example 29 includes the electronic device of any of Examples 17-28, wherein the integrated circuit is conductively coupled to an interposer or a package substrate.

Example 30 includes a method, comprising: receiving a diamond substrate; forming a first dielectric layer on the diamond substrate; and attaching the diamond substrate to a semiconductor substrate, wherein a surface of the semiconductor substrate comprises a second dielectric layer, and wherein the first dielectric layer is bonded to the second dielectric layer using plasma-enhanced bonding.

Example 31 includes the method of Example 30, further comprising, before forming the first dielectric layer on the diamond substrate, cleaning the diamond substrate.

Example 32 includes the method of any of Examples 30-31, wherein forming the first dielectric layer on the diamond substrate comprises depositing a dielectric material over the diamond substrate.

Example 33 includes the method of any of Examples 30-32, further comprising, before attaching the diamond substrate to the semiconductor substrate, polishing the first dielectric layer using chemical mechanical polishing.

Example 34 includes the method of any of Examples 30-33, further comprising, before attaching the diamond substrate to the semiconductor substrate, forming the second dielectric layer on the semiconductor substrate.

Example 35 includes the method of any of Examples 30-34, wherein the first dielectric layer and the second dielectric layer respectively comprise: silicon and nitrogen; silicon and oxygen; silicon, carbon, and nitrogen; silicon and carbon; silicon, oxygen, and carbon; silicon, oxygen, and nitrogen; silicon, oxygen, carbon, and nitrogen; or aluminum and oxygen.

Example 36 includes the method of any of Examples 30-35, wherein attaching the diamond substrate to the semiconductor substrate comprises: bonding the first dielectric layer to the second dielectric layer using plasma-enhanced bonding; and annealing the diamond substrate and the semiconductor substrate.

Example 37 includes the method of any of Examples 30-36, wherein: the semiconductor substrate comprises a semiconductor wafer, wherein the semiconductor wafer comprises a plurality of integrated circuit (IC) dies, wherein the plurality of IC dies are unsingulated; and the method further comprises dicing the semiconductor wafer to singulate the plurality of IC dies.

Example 38 includes the method of any of Examples 30-37, wherein the method is a method of forming a microelectronic assembly, wherein the microelectronic assembly comprises the diamond substrate, the semiconductor substrate, the first dielectric layer, and the second dielectric layer.

1. A microelectronic assembly, comprising:
a semiconductor substrate;
a diamond substrate;
a first dielectric layer on the semiconductor substrate; and
a second dielectric layer on the diamond substrate, wherein the second dielectric layer is bonded to the first dielectric layer.

2. The microelectronic assembly of claim 1, wherein:
the first dielectric layer comprises silicon and oxygen; and
the second dielectric layer comprises (i) silicon and nitrogen or (ii) aluminum and oxygen.

3. The microelectronic assembly of claim 1, wherein the first dielectric layer and the second dielectric layer respectively comprise:
silicon and nitrogen;
silicon and oxygen;
silicon, carbon, and nitrogen;
silicon and carbon;
silicon, oxygen, and carbon;
silicon, oxygen, and nitrogen;
silicon, oxygen, carbon, and nitrogen; or
aluminum and oxygen.

4. The microelectronic assembly of claim 1, wherein:
the first dielectric layer has a thickness in a range of about 50 nanometers to 1 micron; and
the second dielectric layer has a thickness in a range of about 50 nanometers to 100 nanometers.

5. The microelectronic assembly of claim 1, wherein the second dielectric layer is bonded directly to the first dielectric layer.

6. The microelectronic assembly of claim 1, wherein an interface between the first dielectric layer and the second dielectric layer has a bond energy of more than 2.0 joules per square meter.

7. The microelectronic assembly of claim 1, wherein the second dielectric layer has a surface roughness of less than 0.2 nanometers.

8. The microelectronic assembly of claim 1, wherein the diamond substrate has a surface roughness of 0.5 nanometers or higher.

9. The microelectronic assembly of claim 1, wherein the diamond substrate is thermally coupled to the semiconductor substrate, wherein the diamond substrate is to spread heat produced by the semiconductor substrate.

10. The microelectronic assembly of claim 1, wherein the semiconductor substrate comprises an integrated circuit (IC) die.

11. An electronic device, comprising:
an integrated circuit, wherein a surface of the integrated circuit comprises a first dielectric layer; and
a diamond substrate attached to the integrated circuit, wherein a surface of the diamond substrate comprises a second dielectric layer, wherein the second dielectric layer is bonded directly to the first dielectric layer.

12. The electronic device of claim 11, wherein the first dielectric layer and the second dielectric layer respectively comprise:
silicon and nitrogen;
silicon and oxygen;
silicon, carbon, and nitrogen;
silicon and carbon;
silicon, oxygen, and carbon;
silicon, oxygen, and nitrogen;
silicon, oxygen, carbon, and nitrogen; or
aluminum and oxygen.

13. The electronic device of claim 11, wherein:
the first dielectric layer has a thickness in a range of about 50 nanometers to 1 micron; and
the second dielectric layer has a thickness in a range of about 50 nanometers to 100 nanometers.

14. The electronic device of claim 11, further comprising a heat spreader, wherein the heat spreader comprises the diamond substrate.

15. The electronic device of claim 11, wherein the integrated circuit comprises:
an integrated circuit (IC) die; or
a plurality of IC dies, wherein the plurality of IC dies are stacked vertically.

16. A method, comprising:
receiving a diamond substrate;
forming a first dielectric layer on the diamond substrate; and
attaching the diamond substrate to a semiconductor substrate, wherein a surface of the semiconductor substrate comprises a second dielectric layer, and wherein the first dielectric layer is bonded to the second dielectric layer using plasma-enhanced bonding.

17. The method of claim 16, further comprising, before forming the first dielectric layer on the diamond substrate, cleaning the diamond substrate.

18. The method of claim 16, further comprising, before attaching the diamond substrate to the semiconductor substrate, polishing the first dielectric layer using chemical mechanical polishing.

19. The method of claim 16, wherein the first dielectric layer and the second dielectric layer respectively comprise:
silicon and nitrogen;
silicon and oxygen;
silicon, carbon, and nitrogen;
silicon and carbon;
silicon, oxygen, and carbon;
silicon, oxygen, and nitrogen;
silicon, oxygen, carbon, and nitrogen; or
aluminum and oxygen.

20. The method of claim 16, wherein attaching the diamond substrate to the semiconductor substrate comprises:
bonding the first dielectric layer to the second dielectric layer using plasma-enhanced bonding; and
annealing the diamond substrate and the semiconductor substrate.
